(19) United States
(12) Patent Application Publication
(10) Pub. No.: US 2005/0110131 A1
(43) Pub. Date: May 26, 2005

(54) Vertical wafer stacking using an interposer

(76) Inventor: Kevin J. Lee, Beaverton, OR (US)

Correspondence Address: Jan Carol Little-Washington;BLAKELY, SOKOLOFF, TAYLOR & ZAFMAN LLP, Seventh Floor, 12400 Wilshire Boulevard, Los Angeles, CA, 90025-1026, US

(21) Appl. No.: 10/720,649

(22) Filed: Nov. 24, 2003

(51) Int. Cl. H01L 23/053

(52) U.S. Cl. 257/701; 257/774

(57) ABSTRACT

Embodiments of the present invention provide a method of joining two semiconductor wafers face-to-face using an interposer. One embodiment includes a wafer stack comprising a first wafer having a first metal pattern disposed on a top surface, a second wafer having a second metal pattern disposed on a top surface, and an interposer disposed between the top surface of the first wafer and the top surface of the second wafer, the interposer having a pattern of metal vias disposed in a cured thermosetting plastic, the pattern of metal vias being aligned with and electrically coupled to the first metal pattern and the second metal pattern.

### BACKGROUND

1. Field

Embodiments of the present invention relate to integrated circuits and, in particular, to integrated circuit fabrication processes.

2. Discussion of Related Art

In the integrated circuit fabrication industry, it has been common to build several different types of devices (e.g., processor, memory) onto a single silicon wafer. Unfortunately, the optimal process for fabricating one type of device on a wafer may different than the optimal process for fabricating another type of device. Recently, wafer stacking technology has emerged where one wafer has one type of device and a second wafer has another type of device and the two finished wafers are then stacked, bonded, and electrically interconnected to each other. An advantage of the wafer stacking process is that the wafer fabrication process is optimized for the specific type of device on each individual wafer. This technology does suffer from some limitations, however.

One limitation is that there is an air gap in between the two bonded wafers that makes it easy for water, ionic contaminants (e.g., corrosive sodium), or other contaminants to get into the parts on the wafers after the wafers are bonded. The air gap thus presents reliability issues for the wafer stack.

Another limitation concerns the wafer stack after the wafers are bonded together. For instance, when the bottom side of the top wafer is ground back to expose the vias for electrical connection to other devices, an unsupported silicon overhang or ledge remains. The overhang is so thin that it may break.

### BRIEF DESCRIPTION OF THE DRAWINGS

In the drawings, like reference numbers generally indicate identical, functionally similar, and/or structurally equivalent elements. The drawing in which an element first appears is indicated by the leftmost digit(s) in the reference number, in which:

FIG. 1 is a cross-section view of wafer stack according to an embodiment of the present invention;

FIG. 2 is a flowchart illustrating a process for fabricating the wafer stack illustrated in FIG. 1 according to an embodiment of the present invention;

FIGS. 3 through 9 illustrate cross-section views of stages of fabrication of the wafer stack illustrated in FIG. 1 using the process illustrated in FIG. 2 according to an embodiment of the present invention;

FIG. 10 is a flowchart illustrating a process for fabricating the wafer stack illustrated in FIG. 1 according to an alternative embodiment of the present invention

FIGS. 11 through 13 are cross-section views of stages of fabrication of the wafer stack illustrated in FIG. 1 using the process illustrated in FIG. 10 according to an embodiment of the present invention;

FIG. 14 is a cross-section view of a wafer stack according to an alternative embodiment of the present invention;

FIG. 15 illustrates a pre-assembly interposer suitable for implementing the interposer depicted in FIG. 14 according to an embodiment of the present invention;

FIG. 16 is a high-level block diagram of a cellular communication system fabricated according to an embodiment of the present invention.

### DETAILED DESCRIPTION OF THE ILLUSTRATED EMBODIMENTS

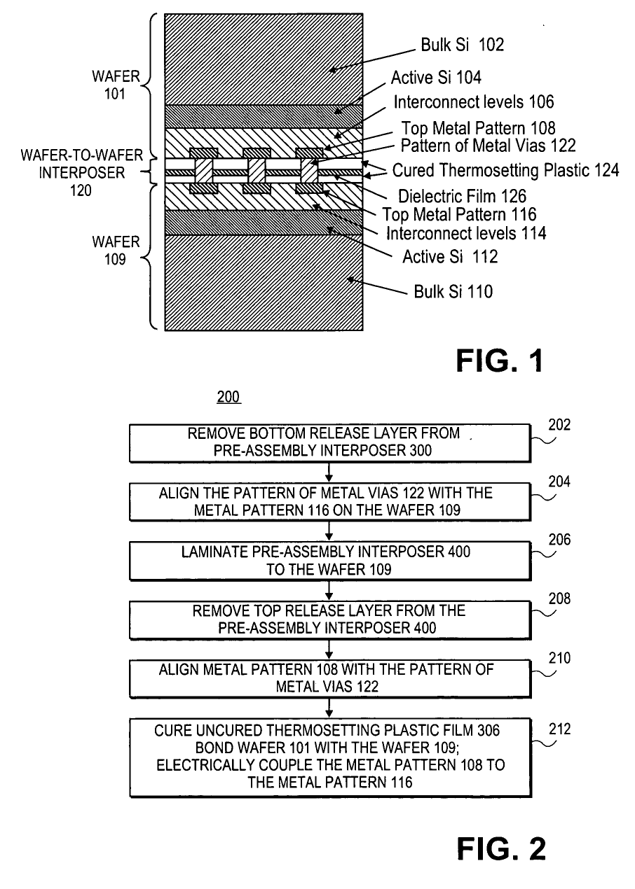

FIG. 1 is a cross-section view of a wafer stack 100 according to an embodiment of the present invention. The wafer stack 100 includes a first wafer 101, which is fabricated using known state-of-the-art techniques. The wafer 101 includes a layer of bulk silicon 102 on the bottom, a layer of active silicon 104 on the bulk silicon 102, one or more metal interconnect levels 106 on the active silicon, and a top metal pattern 108 on the interconnect levels 106.

The wafer stack 100 also includes a second wafer 109, which is fabricated using known state-of-the-art techniques. The wafer 109 includes a layer of bulk silicon 110 on the bottom, a layer of active silicon 112 on the bulk silicon 110, one or more interconnect levels 114 on the active silicon 112, and a top metal pattern 116 on the metal interconnects 114. Note that the wafer 101 is turned upside down so that the wafer 101 and the wafer 109 are bonded face-to-face.

The illustrated wafer stack 100 also includes a wafer-to-wafer interposer 120 disposed between the wafer 101 and the wafer 109. The illustrated interposer 120 includes a pattern of metal vias 122 disposed in a cured thermosetting plastic 124. The pattern of metal vias 122 is aligned with the metal pattern 108 and the metal pattern 116. The interposer 120 also may include a dielectric film 126 disposed in the cured thermosetting plastic 124.

The interconnect levels 106, the metal pattern 108, the interconnect levels may be copper. There may be a diffusion bond between the metal pattern 108 and the pattern of metal vias 122. Alternatively, there may be a solder bond between the metal pattern 108 and the pattern of metal vias 122. The interconnect levels 114 and the metal pattern 116 may be copper. The copper on the metal pattern 116 may have a solder bond with the pattern of metal vias 122. Alternatively, the copper on the metal pattern 116 may have a diffusion bond with the pattern of metal vias 122. The result is that the pattern of metal vias 122 electrically couples the wafer 101 to the wafer 109.

The cured thermosetting plastic 124 may be a polyimide material, an epoxy material, or other suitable material. After reading the description herein, a person of ordinary skill in the relevant art will readily recognize how to implement embodiments of the present invention using various thermosetting plastics.

The dielectric film 126 may be a polyimide film.

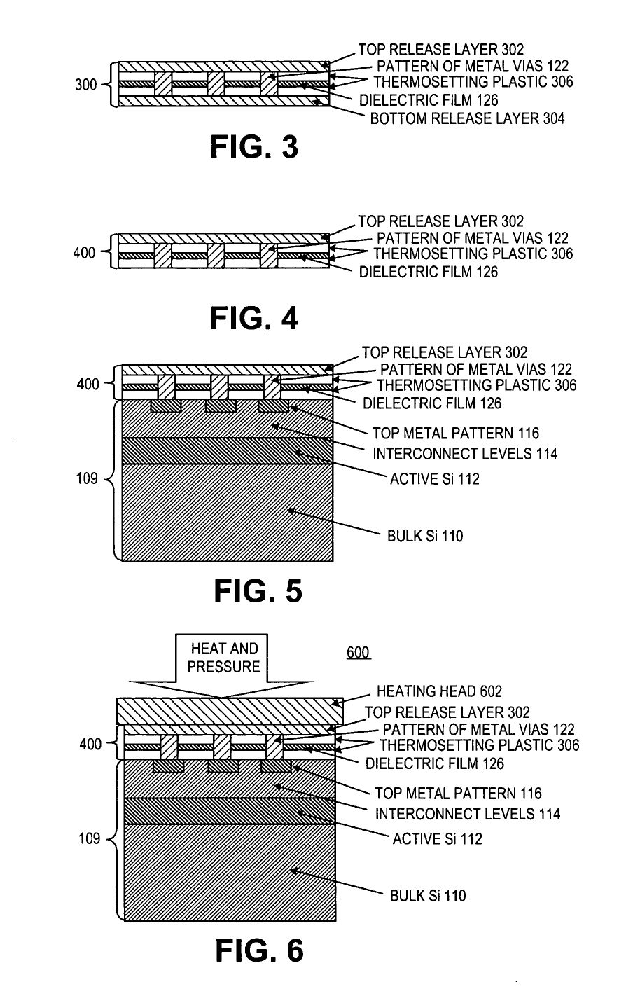

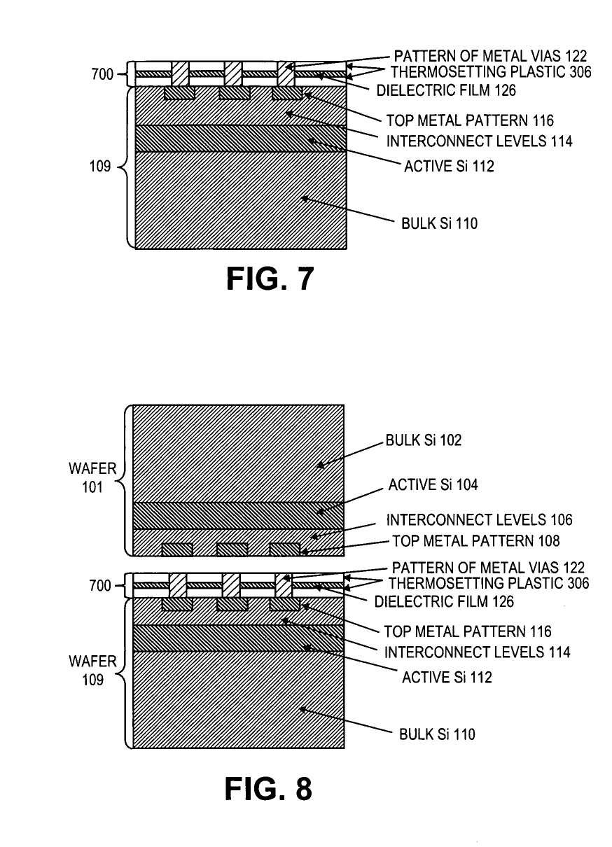

FIG. 2 is a flowchart illustrating a process 200 for fabricating the wafer stack 100 according to an embodiment of the present invention. FIGS. 3 through 9 are cross-section views of stages of fabrication of the wafer stack 100 using the process 200 according to an embodiment of the present invention. The operations of the process 200 are described as multiple discrete blocks performed in turn in a manner that is most helpful in understanding embodiments of the invention. However, the order in which they are described should not be construed to imply that these operations are necessarily order dependent or that the operations be performed in the order in which the blocks are presented.

Of course, the process 200 is only an example process and other processes may be used to implement embodiments of the present invention. A machine-accessible medium with machine-readable instructions thereon may be used to cause a machine (e.g., a processor) to perform the process 200.

The process 200 is described with respect to the interposer 120 including the dielectric film 126. However, it is to be understood that the process 200 also may be used with the interposer 120 without the dielectric film 126. After reading the description herein, a person of ordinary skill in the relevant art will readily recognize how to implement embodiments of the present invention using the interposer 120 without the dielectric film 126.

FIG. 3 shows a pre-assembly interposer 300 according to an embodiment of the present invention. The pre-assembly interposer 300 includes a top release layer 302, a bottom release layer 304, uncured thermosetting plastic film 306 disposed between the top release layer 302 and the bottom release layer 304, and the dielectric film 126, and the pattern of metal vias 122 disposed in the thermosetting plastic film 306.

The top release layer 302 and the bottom release layer 304 may be any suitable backing paper with a Teflon-like coating, for example. In this embodiment, the top release layer 302 and the bottom release layer 304 may lightly adhere to the thermosetting plastic film 306 and the pattern of metal vias 122.

The uncured thermosetting plastic film 306 may be an epoxy material that cures at relatively low temperature (e.g., approximately 180 to 200 C).

Known flexible printed circuit board (PCB) technology may be used to dispose the dielectric film 126 and the pattern of metal vias 122 in the uncured thermosetting plastic film 306. Alternatively, known screen-printing technology may be used to dispose the pattern of metal vias 122 in the uncured thermosetting plastic film 306.

In a block 202, the bottom release layer 304 is removed from the pre-assembly interposer 300. FIG. 4 illustrates a pre-assembly interposer 400 according to an embodiment of the present invention, in which the bottom release layer 304 is removed. In one embodiment, the bottom release layer 304 is peeled off. Equipment suitable for removing the bottom release layer 304 from the pre-assembly interposer 300 are known (e.g., equipment used to remove photoresist backing) and as such will not be described in further detail herein.

In a block 204, the pattern of metal vias 122 is aligned with the metal pattern 116 on the wafer 109. FIG. 5 illustrates the pre-assembly interposer 400 having the pattern of metal vias 122 aligned with the metal pattern 116.

In a block 206, the uncured thermosetting plastic 306 is laminated to the wafer 109. FIG. 6 illustrates a system 600 according to an embodiment of the present invention, in which a heating head 602 is applied to the pre-assembly interposer 400 to laminate the pre-assembly interposer 400 to the wafer 109. Equipment with heating heads suitable for laminating the pre-assembly interposer 400 to the wafer 109 is known and as such will not be described in further detail herein.

In a block 208, the top release layer 302 is removed from the pre-assembly interposer 400. FIG. 7 illustrates a pre-assembly interposer 700 according to an embodiment of the present invention, in which the top release layer 302 is removed. In one embodiment, the top release layer 302 is peeled off.

In a block 210, the metal pattern 108 is aligned with the pattern of metal vias 122. FIG. 8 shows an assembly 800 in which the metal pattern 108 on the wafer 101 is aligned with the pattern of metal vias 122 according to an embodiment of the present invention.

In a block 212, the uncured thermosetting plastic film 306 is cured to bond the wafer 101 with the wafer 109 and wafer 101. The assembly 800 also is heated to bond the pattern of metal vias 122 to the metal pattern 108 on the wafer 101 and to the metal pattern 116 on the wafer 109. FIG. 9 illustrates the heating head 602 being applied to the assembly 800 according to an embodiment of the present invention.

In one embodiment, the pattern of metal vias 122, is solder bonded to the metal pattern 108 and/or to the metal pattern 116. In an alternative embodiment, the pattern of metal vias 122 is diffusion bonded to the metal pattern 108 and/or to the metal pattern 116.

When the thermosetting plastic 306 in the wafer stack 900 is cured, the result is the wafer stack 100 having the wafer 101, the wafer 109, and the interposer 120 between them. The cured thermosetting plastic film 124 fills the gap between the wafer 101 and the wafer 109. The cured thermosetting plastic film 120 also provides support for the thin layer of silicon remaining after the bulk silicon 102 has been ground back to connect the wafer 101 to other devices.

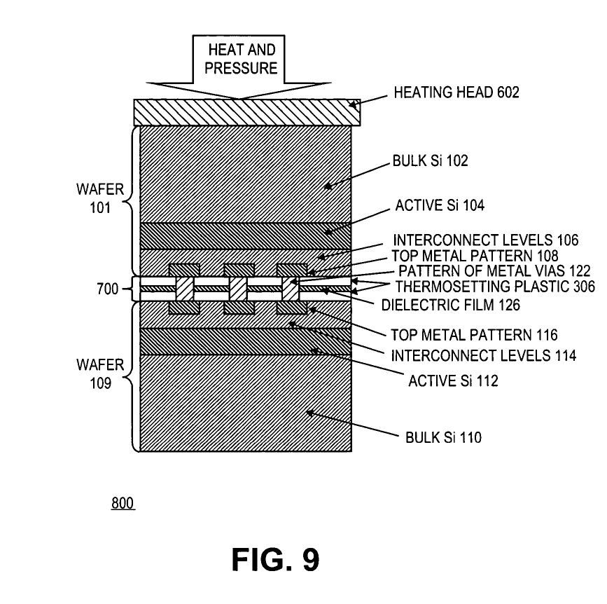

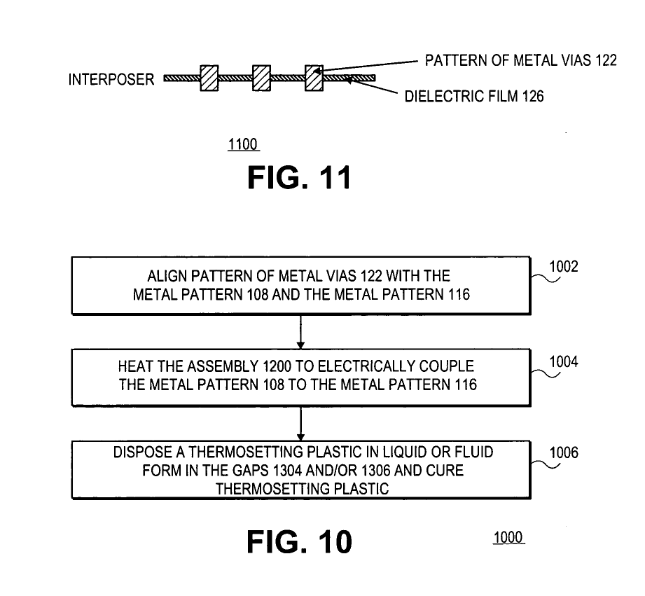

The wafer stack 100 may be fabricated using a different process than the process 200. FIG. 10 is a flowchart illustrating a process 1000 for fabricating the wafer stack 100 according to an alternative embodiment of the present invention. FIGS. 11 through 14 are cross-section views of stages of fabrication of the wafer stack 100 using the process 1000 according to an embodiment of the present invention.

The operations of the process 1000 are described as multiple discrete blocks performed in turn in a manner that is most helpful in understanding embodiments of the invention. However, the order in which they are described should not be construed to imply that these operations are necessarily order dependent or that the operations be performed in the order in which the blocks are presented. Of course, the process 1000 is only an example process and other processes may be used to implement embodiments of the present invention. A machine-accessible medium with machine-readable instructions thereon may be used to cause a machine to perform the process 1000.

FIG. 11 shows a pre-assembly interposer 1100 according to an embodiment of the present invention. The pre-assembly interposer 1100 includes the pattern of metal vias 122 disposed in the dielectric film 126.

In a block 1002, the pattern of metal vias 122 is aligned with the metal pattern 108 on the wafer 101 and the metal pattern 116 on the wafer 1009. FIG. 12 illustrates an assembly 1200 in which the pattern of metal vias 122 is aligned with the metal pattern 108 on the wafer 101 and the metal pattern 116 on the wafer 109 according to an embodiment of the present invention.

In a block 1004, the assembly 1200 is heated to electrically couple the metal pattern 108 to the metal pattern 116. FIG. 13 illustrates a system 1300 according to an embodiment of the present invention, in which the heating head 602 is applied to the pre-assembly wafer stack 1200. The pattern of metal vias 122 is bonded to the metal pattern 108 and to the metal pattern 116 to electrically couple the metal pattern 108 to the metal pattern 116.

Note that in the illustrated embodiment, a gap 1304 (e.g., air gap) exists between the wafer 101 and the pattern of metal vias 122. A gap 1306 (e.g., air gap) also exists between the pattern of metal vias 122 and the wafer 109. In a block 1006, a thermosetting plastic in liquid or fluid form may be disposed in the gaps 1304 and/or 1306 and cured using high heat. The thermosetting plastic may be a polyimide material, an epoxy material, a liquid precursor epoxy, or other suitable material that melts at low temperature, for example.

In one embodiment, a known injection molding process may be used in which pressure and mild heat liquefies a plastic and disposes the liquefied plastic in the gaps 1304 and/or 1306. The injection process may utilize capillary action, vacuum, positive pressure, or a combination thereof, to dispose the thermosetting plastic material into the gaps 1304 and/or 1306.

Heretofore, capillary action did not work when attempting to fill the gap between wafers fabricated without an interposer because the gap between wafers fabricated without an interposer is only a couple thousand angstroms high, and thermosetting plastic materials will not readily flow from the edges of the wafers into the center when the distance from the wafer edge to the wafer center is large (e.g., approximately 150 mm in the case of a 300 mm diameter silicon wafer). The gaps between wafers created using interposers according to embodiments of the present invention are large enough to enable capillary action to be used on wafers with such large center-to-edge distances.

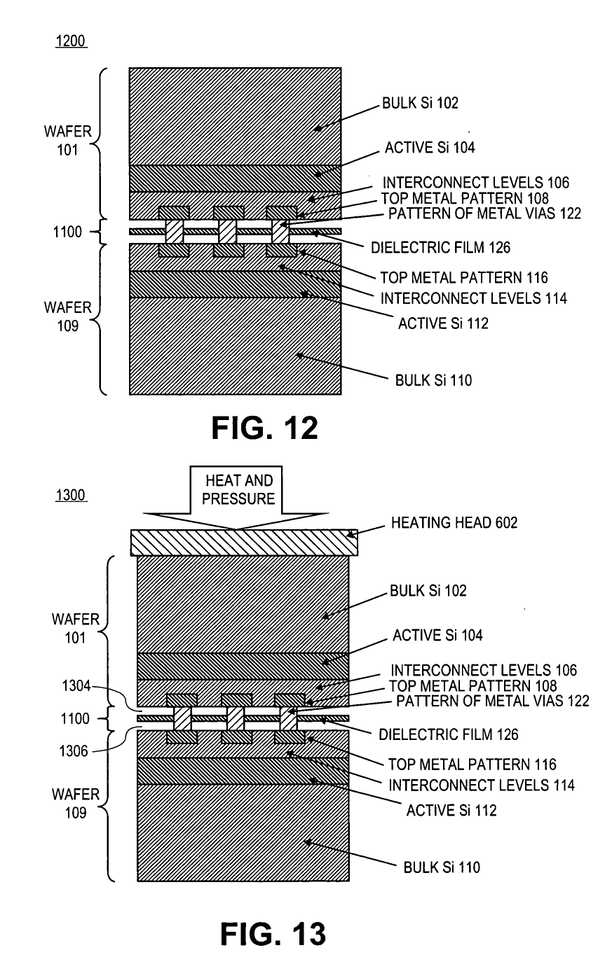

FIG. 14 is a cross-section view of a wafer stack 1400 according to an alternative embodiment of the present invention. The wafer stack 1400 includes a first wafer 1401, which is fabricated using known state-of-the-art techniques. The wafer 1401 includes a layer of bulk silicon 1402 on the bottom, a layer of active silicon 1404 on the bulk silicon 1402, one or more metal interconnect levels 106 on the active silicon, and a top metal pattern 1408 on the interconnect levels 106.

The wafer stack 1400 also includes a second wafer 1409, which is fabricated using known state-of-the-art techniques. The wafer 1409 includes a layer of bulk silicon 1410 on the bottom, a layer of active silicon 1412 on the bulk silicon 1410, one or more interconnect levels 1414 on the active silicon 1412, and a metal pattern 1416 on the metal interconnects 1414. Note that the wafer 1401 is turned upside down so that the wafer 1401 and the wafer 1409 are bonded face-to-face.

The illustrated wafer stack 1400 also includes a wafer-to-wafer interposer 1420 disposed between the wafer 1401 and the wafer 1409. The illustrated interposer 1420 includes a pattern of metal vias 1422 that is disposed in a cured thermosetting plastic 1424. The pattern of metal vias 1422 is aligned with the metal pattern 108 and the metal pattern 116. The interposer 1420 does not include a dielectric film.

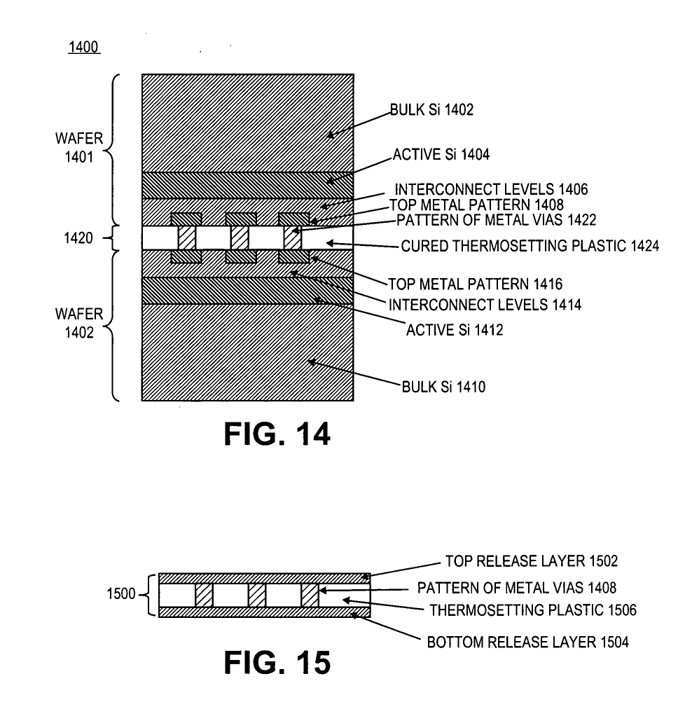

In one embodiment of the present invention, the illustrated wafer stack 1400 may be fabricated using a process similar to the process 200. FIG. 15 shows a pre-assembly interposer 1500 suitable for implementing the interposer 1420 according to an embodiment of the present invention. The pre-assembly interposer 1500 includes a top release layer 1502, a bottom release layer 1504, uncured thermosetting plastic film 1506, and the pattern of metal vias 1408. After reading the description herein a person of ordinary skill in the relevant art will readily recognize how to implement the wafer stack 1400 using a process similar to the process 200.

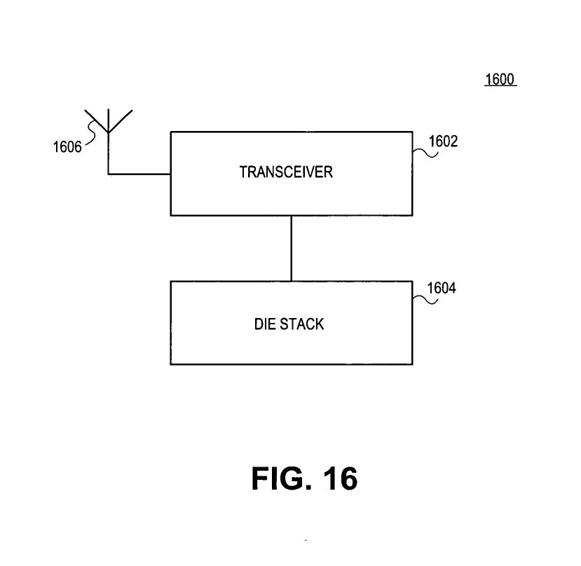

FIG. 16 is a high-level block diagram of a cellular communication system 1600 according to an embodiment of the present invention. The system 1600 may transmit a wireless signal (e.g., radio frequency (RF) signal) for reception by another cellular communication system (not shown). The example system 1600 includes a transceiver 1602 coupled to a die stack 1604, and an antenna 1606.

In one embodiment, the transceiver 1602 may be a Global System for Mobile Communications (GSM) transceiver. Circuitry for implementing GSM transceivers is well known. In an alternative embodiment, the transceiver 1602 may be a Personal Communication Service (PCS) transceiver. Circuitry for implementing PCS transceivers is well known.

The die stack 1604 may be a die stack produced by cutting up the wafer stack 100, the wafer stack 1400, or any other wafer stack fabricated according to embodiments of the present invention into individual die stacks. In one embodiment, the die stack 1604 may include a central processing unit (CPU) bonded to a static random access memory (SRAM) according to embodiments of the present invention.

The antenna 1606 may be a dipole antenna. Dipole antennas are well known.

Embodiments of the present invention may be implemented using hardware, software, or a combination thereof. In implementations using software, the software may be stored on a machine-accessible medium.

A machine-accessible medium includes any mechanism that provides (i.e., stores and/or transmits) information in a form accessible by a machine (e.g., a computer, network device, personal digital assistant, manufacturing tool, any device with a set of one or more processors, etc.). For example, a machine-accessible medium includes recordable and non-recordable media (e.g., read only memory (ROM), random access memory (RAM), magnetic disk storage media, optical storage media, flash memory devices, etc.), as well as electrical, optical, acoustic, or other form of propagated signals (e.g., carrier waves, infrared signals, digital signals, etc.).

In the above description, numerous specific details, such as particular processes, materials, devices, and so forth, are presented to provide a thorough understanding of embodiments of the invention. One skilled in the relevant art will recognize, however, that the embodiments of the present invention can be practiced without one or more of the specific details, or with other methods, components, etc. In other instances, well-known structures or operations are not shown or described in detail to avoid obscuring the understanding of this description.

Reference throughout this specification to “one embodiment” or “an embodiment” means that a particular feature, structure, process, block, or characteristic described in connection with an embodiment is included in at least one embodiment of the present invention. Thus, the appearance of the phrases “in one embodiment” or “in an embodiment” in various places throughout this specification does not necessarily mean that the phrases all refer to the same embodiment. The particular features, structures, or characteristics may be combined in any suitable manner in one or more embodiments.

The terms used in the following claims should not be construed to limit embodiments of the invention to the specific embodiments disclosed in the specification and the claims. Rather, the scope of embodiments of the invention is to be determined entirely by the following claims, which are to be construed in accordance with established doctrines of claim interpretation.

1. An apparatus, comprising:
a first wafer having a first metal pattern disposed on a top surface;
a second wafer having a second metal pattern disposed on a top surface; and
an interposer disposed between the top surface of the first wafer and the top surface of the second wafer, the interposer having a pattern of metal vias disposed in a cured thermosetting plastic, the pattern of metal vias being aligned with and electrically coupled to the first metal pattern and the second metal pattern.

2. The apparatus of claim 1, wherein the interposer further comprises a dielectric film disposed in the cured thermosetting plastic.

3. The apparatus of claim 1, wherein the cured thermosetting plastic comprises a polyimide material.

4. The apparatus of claim 3, wherein the cured thermosetting plastic comprises an epoxy material.

5. A method, comprising:
removing a bottom release layer from an interposer, the interposer having a pattern of metal vias disposed in a thermosetting plastic film;
aligning the pattern of metal vias with a first wafer metalized pattern disposed on a first wafer;
laminating the thermosetting plastic film to the first wafer;
removing a top release layer from the interposer;
aligning the pattern of metal vias with a second wafer metalized pattern disposed on a second wafer;
curing the thermosetting plastic film; and
electrically bonding the first wafer metalized pattern to the second wafer metalized pattern through the pattern of metal vias.

6. The method of claim 5, wherein electrically bonding the first wafer metalized pattern to the second wafer metalized pattern through the pattern of metal vias comprises solder bonding the first wafer metalized pattern to the second wafer metalized pattern through the pattern of metal vias.

7. The method of claim 5, wherein electrically bonding the first wafer metalized pattern to the second wafer metalized pattern through the pattern of metal vias comprises diffusion bonding the first wafer metalized pattern to the second wafer metalized pattern through the pattern of metal vias.

8. A method, comprising:
aligning a pattern of metal vias disposed in a dielectric film with a first wafer metalized pattern on a first wafer;
aligning the pattern of metal vias with a second wafer metalized pattern on a second wafer;
heating the first wafer to electrically bond the first wafer metalized pattern to the second wafer metalized pattern through the pattern of metal vias;
disposing a thermosetting plastic in fluid form in a gap between the first wafer and the second wafer; and
curing the thermosetting plastic.

9. The method of claim 8, wherein heating the first wafer to electrically bond the first wafer metalized pattern to the second wafer metalized pattern through the pattern of metal vias comprises at least one of forming a first solder bond between the first wafer metalized pattern and the pattern of metal vias or forming a second solder bond between the second wafer metalized pattern and the pattern of metal vias.

10. The method of claim 8, wherein heating the first wafer to electrically bond the first wafer metalized pattern to the second wafer metalized pattern through the pattern of metal vias comprises at least one of forming a first diffusion bond between the first wafer metalized pattern and the pattern of metal vias or forming a second diffusion bond between the second wafer metalized pattern and the pattern of metal vias.

11. The method of claim 8, further comprising disposing a polyimide in the gap between the first wafer and the second wafer.

12. The method of claim 8, further comprising disposing an epoxy in the gap between the first wafer and the second wafer.

13. The method of claim 8, further comprising using capillary action to dispose the thermosetting plastic in the gap between the first wafer and the second wafer.

14. The method of claim 13, further comprising using a vacuum to dispose the thermosetting plastic in the gap between the first wafer and the second wafer.

15. The method of claim 13, further comprising applying a positive pressure to the thermosetting plastic to dispose the thermosetting plastic in the gap between the first wafer and the second wafer.

16. A system, comprising:
a transceiver to transmit a wireless signal; and
a die stack comprising:
a central processing unit (CPU) die having a CPU metal pattern on a top surface;
a memory having an memory metal pattern on a top surface; and
an interposer disposed between the top surface of the CPU die and the top surface of the memory die, the interposer having a pattern of metal vias disposed in a cured thermosetting plastic, the pattern of metal vias being aligned with and electrically coupled to the CPU metal pattern and the memory metal pattern,
at least one of the CPU metal pattern or the memory metal pattern being coupled to the transceiver.

17. The system of claim 16, wherein the transceiver is a Global System for Mobile Communication (GSM) transceiver.

18. The system of claim 16, wherein the transceiver is a personal communication system (PCS) transceiver.

19. An article of manufacture, comprising:
a machine-accessible medium including data that, when accessed by a machine, cause the machine to perform the operations comprising:
removing a bottom release layer from an interposer, the interposer having a pattern of metal vias disposed in a thermosetting plastic film;
aligning the a pattern of metal vias with a first wafer metalized pattern on a first wafer and laminating the thermosetting plastic film to the first wafer;
removing a top release layer from interposer and aligning the pattern of metal vias with a second wafer metalized pattern on a second wafer;
curing the thermosetting plastic film to bond the first wafer to the second wafer and heating pattern of metal vias to electrically connect the first wafer metalized pattern to the second wafer metalized pattern.

20. The article of manufacture of claim 19, wherein the machine-accessible medium further includes data that cause the machine to perform operations comprising solder bonding the metalized interconnect to the first wafer metalized pattern and the second wafer metalized pattern.

21. The article of manufacture of claim 19, wherein the machine-accessible medium further includes data that cause the machine to perform operations comprising diffusion bonding the metalized interconnect to the first wafer metalized pattern and the second wafer metalized pattern.

22. An article of manufacture, comprising:
a machine-accessible medium including data that, when accessed by a machine, cause the machine to perform the operations comprising:
aligning a pattern of metal vias of a metalized interconnect disposed in a dielectric material with a first wafer metalized pattern on a first wafer;
aligning the pattern of metal vias with a second wafer metalized pattern on a second wafer;
bonding the pattern of metal vias to the first wafer metalized pattern and the second wafer metalized pattern;
disposing a thermosetting plastic in liquid form between the first wafer and the second wafer; and
curing the thermosetting plastic.

23. The article of manufacture of claim 22, wherein the machine-accessible medium further includes data that cause the machine to perform operations comprising diffusion bonding the metalized interconnect to the first wafer metalized pattern and the second wafer metalized pattern.

24. The article of manufacture of claim 22, wherein the machine-accessible medium further includes data that cause the machine to perform operations comprising solder bonding the metalized interconnect to the first wafer metalized pattern and the second wafer metalized pattern.

25. The article of manufacture of claim 22, wherein the machine-accessible medium further includes data that cause the machine to perform operations comprising disposing a polyimide between the first wafer and the second wafer.

26. The article of manufacture of claim 22, wherein the machine-accessible medium further includes data that cause the machine to perform operations comprising disposing an epoxy between the first wafer and the second wafer.

27. The article of manufacture of claim 22, wherein the machine-accessible medium further includes data that cause the machine to perform operations comprising using capillary action to dispose the thermosetting plastic between the first wafer and the second wafer.

28. The article of manufacture of claim 27, wherein the machine-accessible medium further includes data that cause the machine to perform operations comprising using a vacuum to dispose the thermosetting plastic between the first wafer and the second wafer.

29. The article of manufacture of claim 27, wherein the machine-accessible medium further includes data that cause the machine to perform operations comprising applying a positive pressure to the thermosetting plastic to dispose the thermosetting plastic between the first wafer and the second wafer.
